(19) United States
(12) Patent Application Publication
(10) Pub. No.: US 2023/0207431 A1
(43) Pub. Date: Jun. 29, 2023

(54) SEMICONDUCTOR DEVICE

(71) Applicant: FLOSFIA INC., Kyoto (JP)

(72) Inventors: Hideaki YANAGIDA, Kyoto (JP); Takashi SHINOHE, Kyoto (JP); Hiroyuki ANDO, Kyoto (JP); Yusuke MATSUBARA, Kyoto (JP); Hidehito KITAKADO, Kyoto (JP)

(21) Appl. No.: 18/111,221

(22) Filed: Feb. 17, 2023

Related U.S. Application Data
(63) Continuation-in-part of application No. PCT/JP2021/030687, filed on Aug. 20, 2021.

(30) Foreign Application Priority Data
Aug. 20, 2020 (JP) 2020-139469

(51) Int. Cl. H01L 23/495; H01L 29/872; H01L 29/868; H01L 25/07; H01L 25/18

(52) U.S. Cl. CPC H01L 23/49575; H01L 23/49503; H01L 23/49562; H01L 25/18; H01L 25/072; H01L 29/868; H01L 29/872; H01L 24/48; H01L 2224/48245

(57) ABSTRACT

Provided is a semiconductor device including, a plurality of PN junction diodes each having a negative temperature characteristic and connected to each other in series; a Schottky barrier diode having a positive temperature characteristic and connected to the PN junction diodes in parallel; and a die pad on which at least one of the PN junction diodes and the Schottky barrier diode are mounted commonly.

### CROSS REFERENCE TO RELATED APPLICATION

This application is a continuation-in-part application of International Patent Application No. PCT/JP2021/030687 (Filed on Aug. 20, 2021), which claims the benefit of priority from Japanese Patent Application No. 2020-139469 (filed on Aug. 20, 2020).

The entire contents of the above applications, which the present application is based on, are incorporated herein by reference.

### 1. FIELD OF THE INVENTION

The disclosure relates to a semiconductor device, more specifically, to a semiconductor device that achieves improvement in durability against an overcurrent.

### 2. DESCRIPTION OF THE RELATED ART

Semiconductor devices have been applied to products of every field in recent years and accordingly, have become capable of fulfilling complicated functions of target products by using a plurality of semiconductor elements. Many of these semiconductor devices have a switching function for converting electric power supplied from an external power source and supplying a certain current or voltage to a target product. Furthermore, a structure against an overcurrent is provided in a semiconductor element or in a circuit to allow protection of the target product from an overcurrent.

In an exemplary known semiconductor device, three series-connected PN junction diodes are connected to a Schottky barrier diode in parallel. Generally, a forward voltage of the Schottky barrier diode is larger than a forward voltage of a PN junction diode. Thus, if one Schottky barrier diode and one PN junction diode are connected to each other in parallel, a forward current flows in the PN junction diode in a normal operation period. Meanwhile, setting a total of forward voltages of the three series-connected PN junction diodes greater than a forward voltage of one Schottky barrier diode allows electrical conduction through the PN junction diode only on the occurrence of an overcurrent such as a surge current. As a result, the Schottky barrier diode is protected from the overcurrent.

### SUMMARY OF THE INVENTION

According to an example of the present disclosure, there is provided a semiconductor device including: a plurality of PN junction diodes each having a negative temperature characteristic and connected to each other in series; a Schottky barrier diode having a positive temperature characteristic and connected to the PN junction diodes in parallel; and a die pad on which at least one of the PN junction diodes and the Schottky barrier diode are mounted commonly.

According to an example of the present disclosure, there is provided a semiconductor device including: a plurality of PN junction diodes each having a negative temperature characteristic and connected to each other in series; a Schottky barrier diode having a positive temperature characteristic and connected to the PN junction diodes in parallel; a plurality of first die pad areas on which the PN junction diodes are mounted; and a second die pad area on which the Schottky barrier diode is mounted. At least one of the first die pad areas and the second die pad area are thermally connected to each other.

According to an example of the present disclosure, there is provided a semiconductor device including: a PN junction diode having a negative temperature characteristic; a MOSFET (metal-oxide-semiconductor field effect transistor) having a positive temperature characteristic and connected to the PN junction diode in parallel; and a die pad on which the PN junction diode and the MOSFET are mounted commonly.

According to an example of the disclosure, there is provided a semiconductor device including: a plurality of PN junction diodes each having a negative temperature characteristic; a MOSFET (metal-oxide-semiconductor field effect transistor) having a positive temperature characteristic and connected to the PN junction diodes in parallel; a first die pad area on which the PN junction diodes are mounted; and a second die pad area on which the MOSFET is mounted, the first die pad area and the second die pad area being thermally connected to each other.

Thus, in a semiconductor device of the present disclosure, the semiconductor device that achieves improvement in durability against an overcurrent while encouraging size reduction and higher density is provided.

### BRIEF DESCRIPTION OF THE DRAWINGS

FIG. 1 is a plan view showing an internal layout of a semiconductor device according to a first embodiment of the disclosure.

FIG. 2 is a plan view showing an internal layout of a semiconductor device according to a second embodiment of the disclosure.

FIG. 3 is a plan view showing an internal layout of a semiconductor device according to a third embodiment of the disclosure.

FIG. 4 is a plan view showing an internal layout of a semiconductor device according to a fourth embodiment of the disclosure.

FIG. 5 is a perspective view showing the internal layout of the semiconductor device according to the fourth embodiment of the disclosure.

FIG. 6 is a side view showing an internal layout of a semiconductor device according to a fifth embodiment of the disclosure.

FIG. 7 is a schematic circuit configuration diagram showing the semiconductor device according to the first embodiment of the disclosure.

FIG. 8 is a graph showing an I-V curve for explaining the operation of the semiconductor device of the disclosure.

FIG. 9 is a schematic circuit configuration diagram showing a semiconductor device according to a sixth embodiment of the disclosure.

FIG. 10 is a block diagram illustrating an example of a control system applying the semiconductor device according to an embodiment of the disclosure.

FIG. 11 is a circuit diagram illustrating an example of the control system applying the semiconductor device according to an embodiment of the disclosure.

FIG. 12 is a block configuration diagram illustrating another example of the control system applying the semiconductor device according to an embodiment of the disclosure.

FIG. 13 is a circuit diagram illustrating another example of the control system applying the semiconductor device according to an embodiment of the disclosure.

### DETAILED DESCRIPTION

If both the Schottky barrier diode and the PN junction diode have positive temperature characteristics, it becomes more difficult to cause a forward current to flow in each of the diodes as a temperature becomes higher. Mounting the PN junction diode and the Schottky barrier diode on respective die pads makes it possible to prevent thermal interference between these diodes, thereby reducing the occurrence of heating of the PN junction diode due to the influence of heat generation at the Schottky barrier diode. Maintaining the characteristic of a forward current in the PN junction diode allows the PN junction diode to keep the function of conducting an overcurrent of equal to or greater than a certain value.

However, in response to needs for size reduction and higher density of the semiconductor device, providing a large number of die pads thermally independent of each other on a limited mounting surface is not preferred. This is a remarkable issue, particularly in power semiconductor with a large number of mounted semiconductor elements. Moreover, in power semiconductor such as gallium oxide, it is still impossible to take action against an overcurrent satisfactorily and a problem such as failing to ensure sufficient heat dissipation performance is also caused during mounting.

Semiconductor devices according to embodiments of the disclosure will be described below by referring to the drawings.

Embodiments of the present disclosure will be described below with reference to the accompanying drawings. In the following description, the same parts and components are designated by the same reference numerals. The present embodiment includes, for example, the following disclosures.

### [Structure 1]

A semiconductor device including: a plurality of PN junction diodes each having a negative temperature characteristic and connected to each other in series; a Schottky barrier diode having a positive temperature characteristic and connected to the PN junction diodes in parallel; and a die pad on which at least one of the PN junction diodes and the Schottky barrier diode are mounted commonly.

### [Structure 2]

The semiconductor device according to [Structure 1], wherein a total of respective forward voltages of the PN junction diodes is greater than a forward voltage of the Schottky barrier diode.

### [Structure 3]

The semiconductor device according to [Structure 1] or [Structure 2], wherein at least one of the PN junction diodes is a vertical diode.

### [Structure 4]

The semiconductor device according to any one of [Structure 1] to [Structure 3], wherein at least one of the PN junction diodes is stacked on a different one of the PN junction diodes.

### [Structure 5]

The semiconductor device according to any one of [Structure 1] to [Structure 4], wherein all the PN junction diodes are mounted on the same die pad.

### [Structure 6]

The semiconductor device according to any one of [Structure 1] to [Structure 5], wherein each of the PN junction diodes contains silicon.

### [Structure 7]

The semiconductor device according to any one of [Structure 1] to [Structure 6], wherein the PN junction diodes include a PiN diode.

### [Structure 8]

The semiconductor device according to any one of [Structure 1] to [Structure 7], wherein the Schottky barrier diode contains gallium oxide or mixed crystal of gallium oxide.

### [Structure 9]

A semiconductor device including: a plurality of PN junction diodes each having a negative temperature characteristic and connected to each other in series; a Schottky barrier diode having a positive temperature characteristic and connected to the PN junction diodes in parallel; a plurality of first die pad areas on which the PN junction diodes are mounted; and a second die pad area on which the Schottky barrier diode is mounted, at least one of the first die pad areas and the second die pad area being thermally connected to each other.

### [Structure 10]

The semiconductor device according to [Structure 9], wherein at least one of the first die pad areas and the second die pad area are formed integrally with each other.

### [Structure 11]

The semiconductor device according to [Structure 9] or [Structure 10], wherein a total of respective forward voltages of the PN junction diodes is greater than a forward voltage of the Schottky barrier diode.

### [Structure 12]

The semiconductor device according to any one of [Structure 9] to [Structure 11], wherein at least one of the PN junction diodes is a vertical diode.

### [Structure 13]

The semiconductor device according to any one of [Structure 9] to [Structure 12], wherein at least one of the PN junction diodes is stacked on a different one of the PN junction diodes.

### [Structure 14]

The semiconductor device according to any one of [Structure 9] to [Structure 13], wherein all the PN junction diodes are mounted on the same die pad area.

### [Structure 15]

The semiconductor device according to any one of [Structure 9] to [Structure 14], wherein each of the PN junction diodes contains silicon.

### [Structure 16]

The semiconductor device according to any one of [Structure 9] to [Structure 15], wherein the PN junction diodes include a PiN diode.

### [Structure 17]

The semiconductor device according to any one of [Structure 9] to [Structure 16], wherein the Schottky barrier diode contains gallium oxide or mixed crystal of gallium oxide.

### [Structure 18]

A semiconductor device including: a PN junction diode having a negative temperature characteristic; a MOSFET (metal-oxide-semiconductor field effect transistor) having a positive temperature characteristic and connected to the PN junction diode in parallel; and a die pad on which the PN junction diode and the MOSFET are mounted commonly.

### [Structure 19]

A semiconductor device including: a plurality of PN junction diodes each having a negative temperature characteristic; a MOSFET (metal-oxide-semiconductor field effect transistor) having a positive temperature characteristic and connected to the PN junction diodes in parallel; a first die pad area on which the PN junction diodes are mounted; and a second die pad area on which the MOSFET is mounted, the first die pad area and the second die pad area being thermally connected to each other.

### [Structure 20]

A power converter using the semiconductor device according to any one of [Structure 1] to [Structure 19].

### [Structure 21]

A control system using the semiconductor device according to any one of [Structure 1] to [Structure 19].

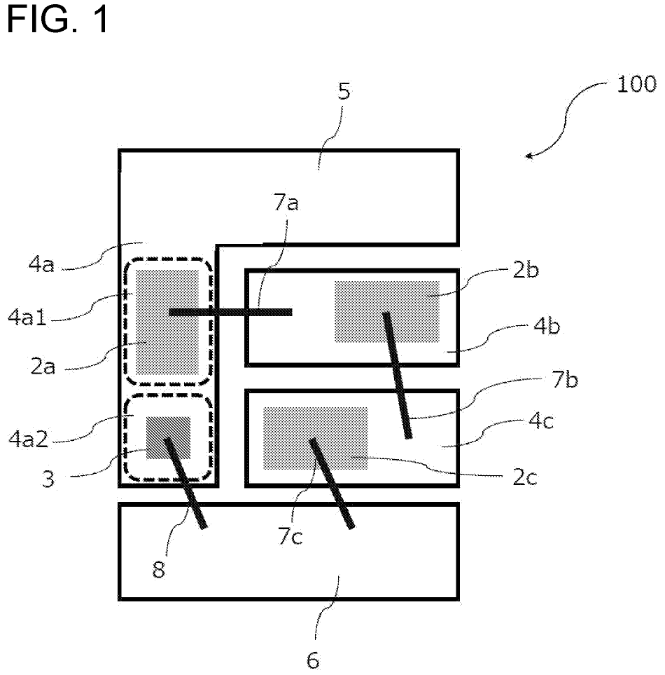

FIG. 1 is a plan view showing an internal layout of a semiconductor device according to a first embodiment of the disclosure. In this drawing, a semiconductor device 100 includes three vertical PN junction diodes 2a, 2b, and 2c each composed of a semiconductor element, and one Schottky barrier diode 3. The PN junction diode 2a and the Schottky barrier diode 3 are mounted on a common die pad 4a. The PN junction diode 2b and the PN junction diode 2c are mounted on a die pad 4b and a die pad 4c respectively.

The semiconductor device 100 further includes a terminal 5 and a terminal 6 for input and output of electric power to and from outside. Respective terminal edges of the terminals 5 and 6 (in FIG. 1, a region in an uppermost part of the terminal 5 in the plane of the sheet and a region in a lowermost part of the terminal 6 in the plane of the sheet) are exposed from a ceramic package and connected to a circuit board, for example.

The terminal 5 is composed of the same member as the die pad 4a and is formed integrally with the die pad 4a. Specifically, as indicated by a dotted line, the die pad 4a has two areas composed of the same member including a first area (first pad area) 4a1 on which the PN junction diode 2a is mounted and a second area (second pad area) 4a2 on which the Schottky barrier diode 3 is mounted. The die pad 4b and the die pad 4c are configured as separate structures spaced from the terminals 5 and 6 in order to avoid mutual electrical and thermal influence between the die pads 4b and 4c and the terminals 5 and 6. The die pads 4a, 4b, and 4c are prepared using a material of high thermal conductivity (copper, for example).

The PN junction diodes 2a, 2b, and 2c are electrically connected to each other through the die pads 4a, 4b, and 4c, and a lead 7a, a lead 7b, and a lead 7c. The PN junction diodes 2a, 2b, and 2c are configured in such a manner as to be connected to each other in series with the terminals 5 and 6 at both ends. Meanwhile, the Schottky barrier diode 3 is connected to the terminal 6 through a lead 8. The Schottky barrier diode 3 is configured in such a manner as to provide electrical conduction across the terminals 5 and 6 and to be connected in parallel to the three series-connected PN junction diodes 2a, 2b, and 2c.

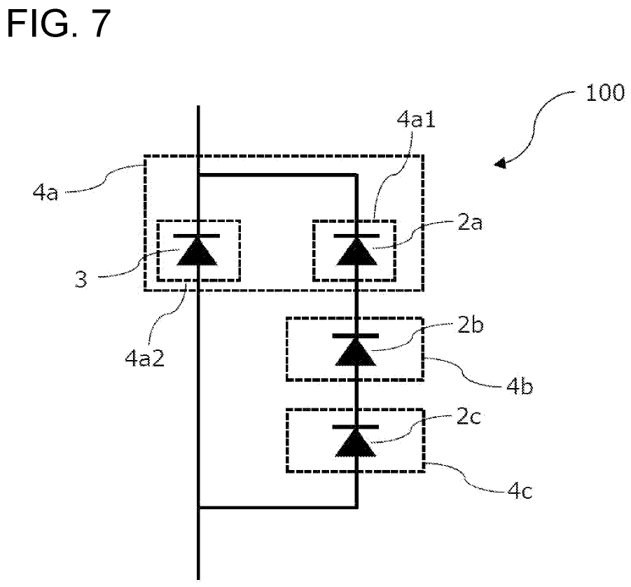

FIG. 7 shows a schematic circuit configuration of the semiconductor device 100 shown in FIG. 1 and shows the die pads 4a, 4b, and 4c on which the PN junction diodes 2a, 2b, and 2c and the Schottky barrier diode 3 are mounted are superimposed on the circuit diagram. By understanding the circuit configuration shown in FIG. 7 as a Schottky barrier diode having an overcurrent protection function, it becomes possible to apply the semiconductor device 100 of the present embodiment to an existing product using a Schottky barrier diode such as an inverter, a converter, or a rectifier.

The PN junction diode used in the present embodiment has a negative temperature characteristic at least under an overcurrent condition, which is namely a PN junction diode having a characteristic that an electrical resistance value decreases in response to temperature increase. In this case, a PN junction diode containing Si is preferred, for example. A PiN diode with an i layer interposed between a P layer and an N layer involved in a PN junction is also usable. This makes it possible to encourage improvement in a breakdown voltage.

Meanwhile, the Schottky barrier diode used in the present embodiment has a positive temperature characteristic at least under an overcurrent condition, which is namely a Schottky barrier diode having a characteristic that an electrical resistance value increases in response to temperature increase. In this case, a Schottky barrier diode containing gallium oxide (Ga₂O₃) is preferred, for example. In particular, in terms of a switching characteristic of a Schottky barrier diode, using corundum gallium oxide (α—Ga₂O₃) is preferred. A Schottky barrier diode containing mixed crystal including gallium oxide is also preferred. A Schottky barrier diode containing mixed crystal with aluminum (Al) or indium (In) is particularly preferred.

A forward voltage of each of the PN junction diodes 2a, 2b, and 2c is lower than a forward voltage of the Schottky barrier diode 3. Meanwhile, a forward voltage determined in a case of connecting the PN junction diodes 2a, 2b, and 2c to each other in series, specifically, a total of the respective forward voltages of the PN junction diodes 2a, 2b, and 2c is set greater than the forward voltage of the Schottky barrier diode 3. For example, the PN junction diodes 2a, 2b, and 2c to be used each have a forward voltage of 0.7 V and the Schottky barrier diode 3 to be used has a forward voltage of 1.5 V.

The semiconductor device 100 is put into actual use by being housed in a ceramic package not shown in the drawings, for example, and is used as a power semiconductor device mounted in various types of power devices, for example.

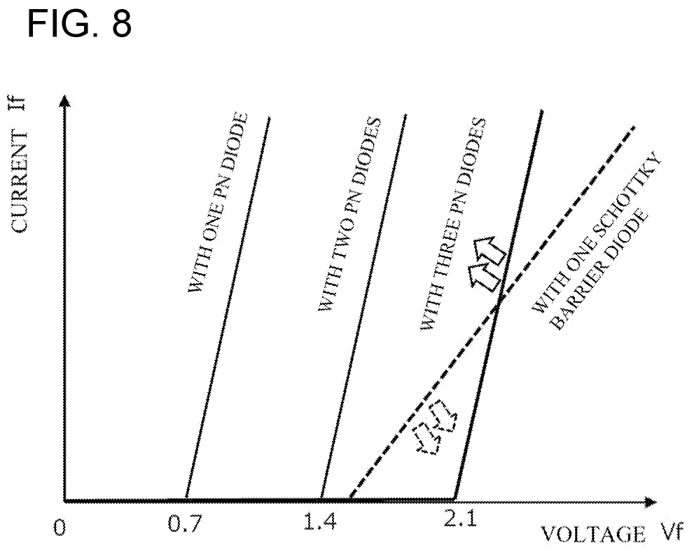

The operation of the semiconductor device 100 according to the first embodiment of the disclosure having the above-described configuration will be described by referring to an I-V characteristic graph in FIG. 8.

If one PN junction diode having a forward voltage of 0.7 V and one Schottky barrier diode having a forward voltage of 1.5 V are connected to each other in parallel, a current flows in the PN junction diode at a forward bias voltage of 0.7 V and a current does not flow in the Schottky barrier diode to operate at a voltage of equal to or greater than 1.5 V. Likewise, if two PN junction diodes each having a forward voltage of 0.7 V are connected to each other in series and are connected in parallel to one Schottky barrier diode having a forward voltage of 1.5 V, a current also flows in the PN junction diodes at a voltage of 1.4 V and the Schottky barrier diode is not caused to operate.

By contrast, if three PN junction diodes each having a forward voltage of 0.7 V are connected to each other in series and are connected in parallel to one Schottky barrier diode having a forward voltage of 1.5 V, a current flows in the Schottky barrier diode at a voltage of 1.5 V so a current does not flow in the three series-connected PN junction diodes having a forward voltage of 2.1 V as a whole. Specifically, by connecting PN junction diodes of an arbitrary number to each other in series in such a manner that a total value of respective partial pressures of these PN junction diodes is greater than a forward voltage value of one Schottky barrier diode, it becomes possible to provide electrical conduction through the series-connected PN junction diodes only on the occurrence of an overcurrent and to cause only the Schottky barrier diode to operate in a normal operation period.

In the semiconductor device 100 according to the first embodiment, a total of respective forward voltages of the PN junction diodes 2a, 2b, and 2c (0.7 V + 0.7 V + 0.7 V = 2.1 V) is greater than a forward voltage of the Schottky barrier diode 3 (1.5 V). This causes a current to flow only in the Schottky barrier diode 3 in the normal operation period to form electrical conduction across the terminals 5 and 6.

On the other hand, on the occurrence of flow of an overcurrent such as a surge current, a high voltage (a voltage significantly beyond 2.1 V) is generated momentarily. In this case, this overcurrent is allowed to be conducted through the three PN junction diodes 2a, 2b, and 2c connected to the Schottky barrier diode 3 in parallel. Specifically, by making design in such a manner as to conduct a forward current through the three series-connected PN junction diodes 2a, 2b, and 2c only on the occurrence of an overcurrent, it becomes possible to prevent damage on the Schottky barrier diode 3 due to the overcurrent.

Furthermore, in the present embodiment, the Schottky barrier diode 3 has a positive temperature characteristic. Thus, a forward voltage becomes larger as a temperature becomes higher to make it more difficult to cause a current to flow. This indicates that a line with dashes shown in FIG. 8 gradually slopes to be approximated to a horizontal direction (gradually lies down). On the other hand, the PN junction diodes 2a, 2b, and 2c each have a negative temperature characteristic. Thus, a forward voltage becomes smaller as a temperature becomes higher to cause a current to flow more easily. This indicates that lines expressed as solid lines in FIG. 8 gradually slope to be approximated to a vertical direction (gradually rises up). Furthermore, as the PN junction diode 2a and the Schottky barrier diode 3 are mounted on the common die pad 4a, heat generated from the Schottky barrier diode 3 is transferred to the PN junction diode 2a to reduce a forward voltage of the PN junction diode 2a further. As a result, the PN junction diode 2a becomes capable of conducting more current therethrough, compared to a case where a PN junction diode and a Schottky barrier diode are mounted on respective die pads. This provides the series-connected PN junction diodes 2a, 2b, and 2c with a forward voltage lower than a total of respective forward voltages of the PN junction diodes 2a, 2b, and 2c at the time of design, making it possible to conduct a generated overcurrent reliably.

Preferably, a total of respective reverse breakdown voltages of the series-connected PN junction diodes 2a, 2b, and 2c is set about equal to or greater than a reverse breakdown voltage of the Schottky barrier diode 3. If the reverse breakdown voltage of the Schottky barrier diode 3 is 600 V, for example, the PN junction diodes 2a, 2b, and 2c to be used each have a reverse breakdown voltage of equal to or greater than 200 V.

In the semiconductor device 100 of the present embodiment to operate in the above-described manner, heat generated from the Schottky barrier diode is transferred to the PN junction diode through the die pad (die pad area). As the PN junction diode has a negative temperature characteristic, it is possible to maintain and improve an electrical conduction characteristic of the PN junction diode in a forward direction against an overcurrent such as a surge current. As a result, the semiconductor device that achieves improvement in durability against an overcurrent while encouraging size reduction and higher density is provided.

If the semiconductor device is applied to a power device, it is preferable to use a semiconductor element having an excellent bandgap characteristic. In the present embodiment, the Schottky barrier diode 3 may be formed using a material including silicon carbide (SiC) or gallium nitride (GaN). Meanwhile, using oxide semiconductor containing gallium oxide (Ga₂O₃) having a wider bandgap characteristic for forming the Schottky barrier diode 3 provides the semiconductor device with higher performance and compactness. Moreover, in the present embodiment, the PN junction diode 2a and the Schottky barrier diode 3 are mounted on the common die pad 4a. This makes it possible to improve the heat dissipation performance of the Schottky barrier diode 3 further. In particular, even if used semiconductor contains gallium oxide of low thermal conductivity or mixed crystal of gallium oxide, it is still possible to reveal the performance of the Schottky barrier diode 3 easily in the semiconductor device. As described above, mounting the PN junction diode and the Schottky barrier diode on the common die pad (die pad area) facilitates temperature increase at the PN junction diode through the diode pad (die pad area), thereby providing the semiconductor device with improved resistance to an overcurrent.

While an operating temperature of the PN junction diode is properly settable in in response to a purpose of application, etc., the PN junction diode is preferably configured to operate at a temperature of equal to or less than 175° C., for example.

Other embodiments of the disclosure will be described below. In the following description, a constituting element common to the first embodiment or common to another embodiment will be given the same sign and explanation thereof overlapping between the embodiments will be omitted.

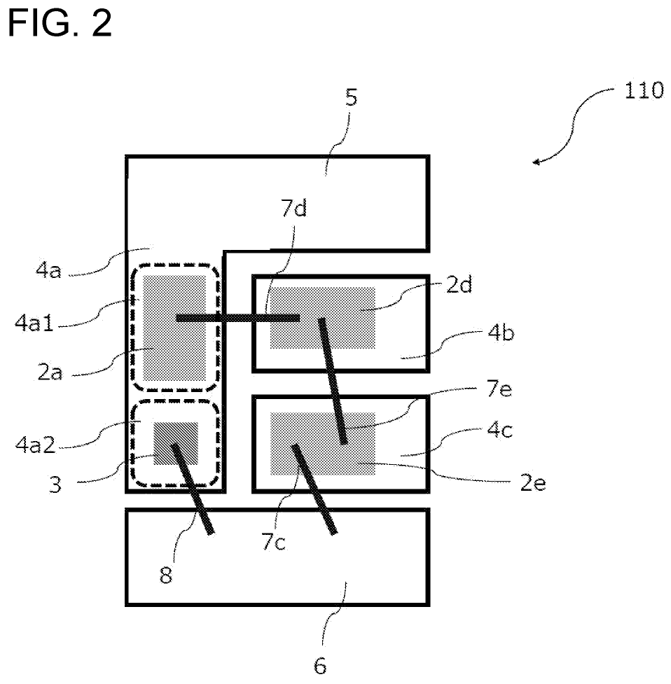

FIG. 2 is a plan view showing an internal layout of a semiconductor device according to a second embodiment of the disclosure. A semiconductor device 110 shown in this drawing is equipped with a PN junction diode 2d and a PN junction diode 2e differing from those of the semiconductor device 100 in FIG. 1. Specifically, the PN junction diode 2a mounted on the first area 4a1 of the die pad 4a is a vertical PN junction diode, and the PN junction diodes 2d and 2e mounted on the die pad 4b and the die pad 4c respectively are both horizontal PN junction diodes. A lead 7d, a lead 7e, and the lead 7c are electrically connected to the PN junction diodes 2a,2d and 2e at the upper surfaces of the PN junction diodes 2a, 2d, and 2e (surfaces on opposite sides of their mounting surfaces and facing the near side of the plane of the sheet of FIG. 2).

In the semiconductor device 110 having the above-described configuration, all the leads 7d, 7e, and 7c are connected to the upper surfaces of the PN junction diodes 2a, 2d, and 2e. This eliminates the need for providing space on the die pads 4a, 4b, and 4c for connection to the leads 7d, 7e, and 7c. This achieves reduction in the areas of the die pads 4a, 4b, and 4c and contributes to size reduction of the semiconductor device 110.

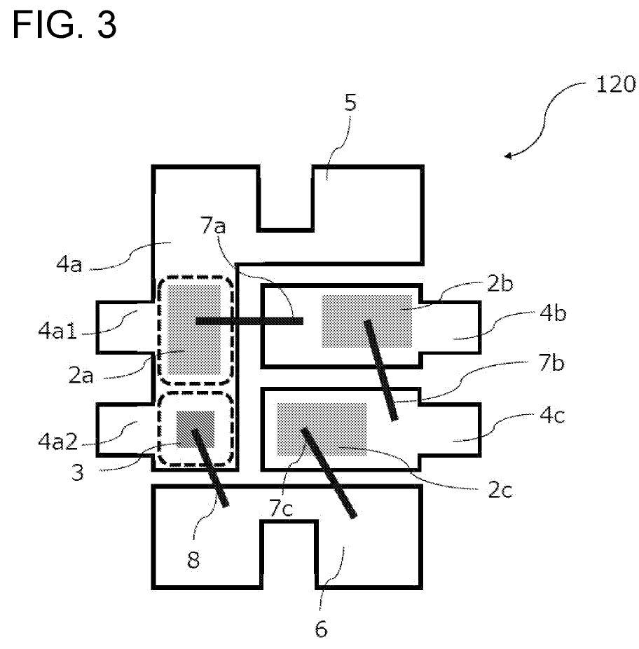

FIG. 3 is a plan view showing an internal layout of a semiconductor device according to a third embodiment of the disclosure. Like the semiconductor device 100 in FIG. 1, a semiconductor device 120 in this drawing is equipped with the three vertical PN junction diodes 2a, 2b, and 2c, and the leads 7a, 7b, and 7c are connected to these diodes. While the die pads 4a, 4b, and 4c, and the terminals 5 and 6 are modified three-dimensionally to appropriate shapes on the assumption that the semiconductor device 120 is to be mounted on a lead frame, they are electrically connected in the same way as that in the semiconductor device 100 of the first embodiment. The semiconductor device 120 having this configuration is expected to achieve effect comparable to that achieved by the first embodiment.

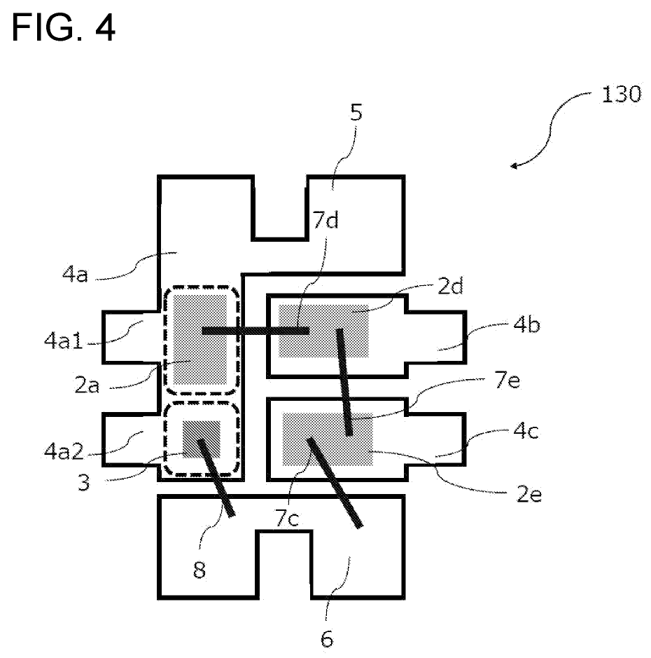

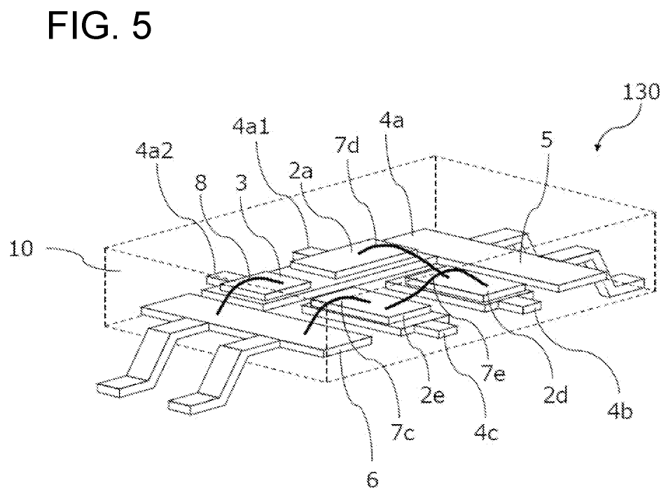

FIG. 4 is a plan view showing an internal layout of a semiconductor device according to a fourth embodiment of the disclosure. FIG. 5 is a perspective view of this internal layout. Like the semiconductor device 110 in FIG. 2, a semiconductor device 130 shown in FIGS. 4 and 5 is equipped with one vertical PN junction diode 2a and two horizontal PN junction diodes 2d and 2e. The leads 7d, 7e, and 7c are connected to these diodes. While the die pads 4a, 4b, and 4c, and the terminals 5 and 6 are modified to appropriate shapes on the assumption that the semiconductor device 130 is to be mounted in a package 10 (indicated by dotted lines in FIG. 5) of a lead frame, they are electrically connected in the same way as that in the semiconductor device 110 of the second embodiment. Preferably, space in the package 10 is molded completely with epoxy resin, for example. If the lead frame corresponds to a lowermost surface of the package 10, it is preferable to mold an upper side from the lead frame surface completely. If the lead frame is at a position around an intermediate height of the package 10, it is preferable to mold both the upper side and a lower side from the lead frame completely. In the present embodiment, all the PN junction diodes 2a, 2d, and 2e, Schottky barrier diode 3, die pads 4a, 4b, and 4c, and leads 7d, 7e, 7c, and 8, and the terminals 5 and 6 (except their parts exposed to the outside of the package 10 and to be used for mounting on a substrate) are molded integrally in the package 10. The semiconductor device 130 having this configuration is expected to achieve effect comparable to that achieved by the second embodiment.

While the package 10 mentioned herein is an SOP (small outline package) as one type of surface mounting. However, each embodiment of the disclosure is implementable in a configuration of mounting on various types of IC packages belonging to surface mounting other than the former surface mounting, insertion mounting, or contact mounting, for example. In response to a purpose of application, design is made arbitrarily in terms of the size of a package, the number of terminals or the widths of the terminals to be mounted on the package, etc.

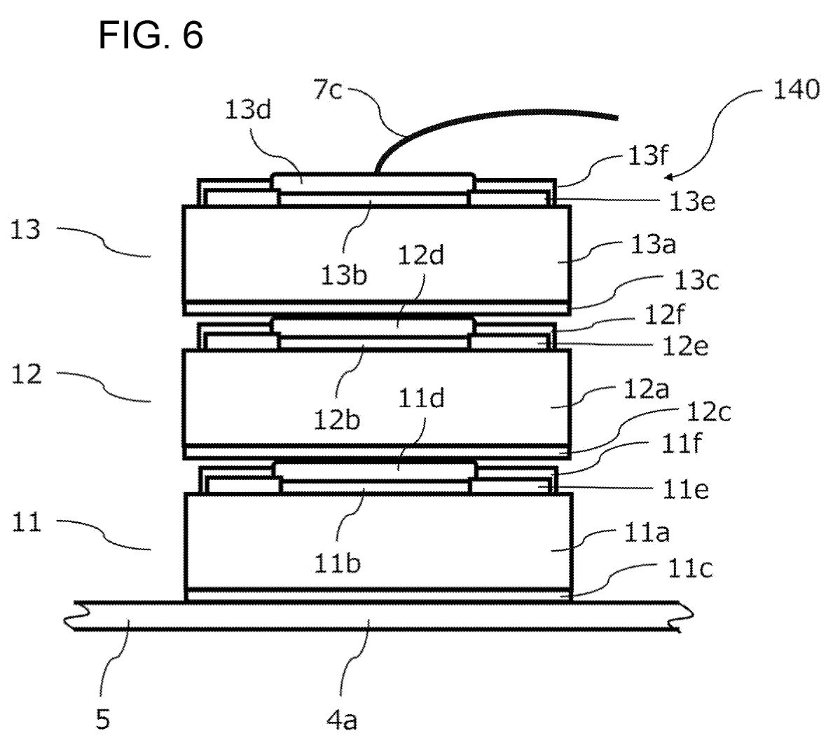

FIG. 6 is a side view showing an internal layout of a semiconductor device according to a fifth embodiment of the disclosure. A semiconductor device 140 according to the present embodiment is characterized in a state where three vertical PN junction diodes 11, 12, and 13 are mounted in such a manner as to be stacked on each other in a direction of their thicknesses. In a plan view, the PN junction diodes 11, 12, and 13 are arranged in the first area 4a1 on the die pad 4a, like the vertical PN junction diode 2a shown in FIG. 1, for example. While the PN junction diodes 11, 12, and 13 all have the same configuration, this configuration will be described in detail by taking the PN junction diode 11 as an example.

The PN junction diode 11 includes a semiconductor body 11a made of p-type and n-type silicon (Si). The semiconductor body 11a has an upper surface where a first electrode film 11b is provided as an anode containing nickel (Ni), and a lower surface where a second electrode film 11c is provided as a cathode containing nickel or titanium (Ti). A wiring film 11d composed of a metal film made of an aluminum-based material such as aluminum (Al), AlSi, or AlSiCu is provided on the first electrode film 11b. The PN junction diode 11 includes a passivation film 11e made of silicon dioxide (SiO₂) or silicon nitride (SiN) and a polyimide film 11f covering the passivation film 11e that are provided as upper surface protective films for the PN junction diode 11. Each of these constituting elements is formed by publicly-known semiconductor manufacturing technique such as film deposition or etching.

The three PN junction diodes 11, 12, and 13 having the same structure are stacked on the same die pad. At this time, electrode films facing each other are electrically connected to each other in series through solder. Furthermore, one end of the lead 7 is connected to a wiring film 13d of the PN junction diode 13 to form connection to the terminal 6. Moreover, the terminal 5 is directly connected to the second electrode film 11c of the PN junction diode 11. To facilitate solder connection between corresponding ones of the wiring films 11d and 12d and the second electrode films 12c and 13c, each of these films may have a surface composed of a layer made of gold (Au) or lead (Pb).

The semiconductor device 140 having the above-described configuration is expected to achieve effect comparable to that achieved by the first embodiment and additionally, allows heat generated from the Schottky barrier diode 3 to be transferred through the die pad 4a to the three stacked PN junction diodes 11, 12, and 13 sequentially. By doing so, the PN junction diodes 11, 12, and 13 each having a negative temperature characteristic is heated effectively to allow an overcurrent to be conducted reliably.

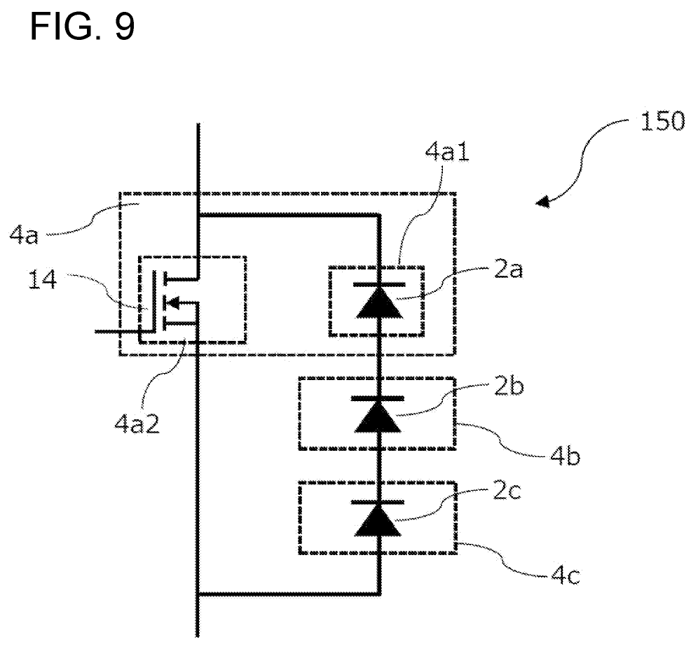

FIG. 9 is a schematic circuit configuration diagram of a semiconductor device according to a sixth embodiment of the disclosure. Like in the schematic circuit configuration of the semiconductor device 100 shown in FIG. 7, a semiconductor device 150 of the present embodiment includes a plurality of PN junction diodes 2a, 2b, and 2c connected to each other in series. The semiconductor device 150 of the present embodiment further includes a MOSFET (metal-oxide-semiconductor field effect transistor) 14 for synchronous rectification instead of the Schottky barrier diode 3 in FIG. 7. In the present embodiment, PN junction diodes of an arbitrary number (one, or two or more) are connected to each other in series, for example, in such a manner that a total value of respective partial pressures (forward voltage values) of these PN junction diodes is greater than a forward voltage value of one MOSFET. By doing so, it becomes possible to provide electrical conduction through the PN junction diode only on the occurrence of an overcurrent and to cause only the MOSFET to operate in a normal operation period. For this reason, if a forward voltage value of one PN junction diode is greater than a forward voltage value of one MOSFET 14, the number of the PN junction diodes may be one. Specifically, in the present embodiment, the number of the PN junction diodes is not limited to that in the configuration shown in FIG. 9. If only one PN junction diode is to be connected, this one PN junction diode is desirably configured to be mounted on the die pad 4a common to the MOSFET 14 for synchronous rectification by being connected in the same way as the PN junction diode 2a in FIG. 9. In another case, this one PN junction diode and the MOSFET 14 for synchronous rectification may be configured to be mounted on respective die pads thermally connected to each other. Like in the above-described embodiments, such a circuit configuration realizes the semiconductor device 150 encouraging improvement in durability of the MOSFET for synchronous rectification against an overcurrent. Like the Schottky barrier diode 3, the MOSFET 14 for synchronous rectification may certainly be formed using a material including silicon carbide (SiC) or gallium nitride (GaN), and may also be formed using oxide semiconductor containing gallium oxide (Ga₂O₃) having a wider bandgap characteristic. By doing so, the semiconductor device is provided with higher performance and compactness.

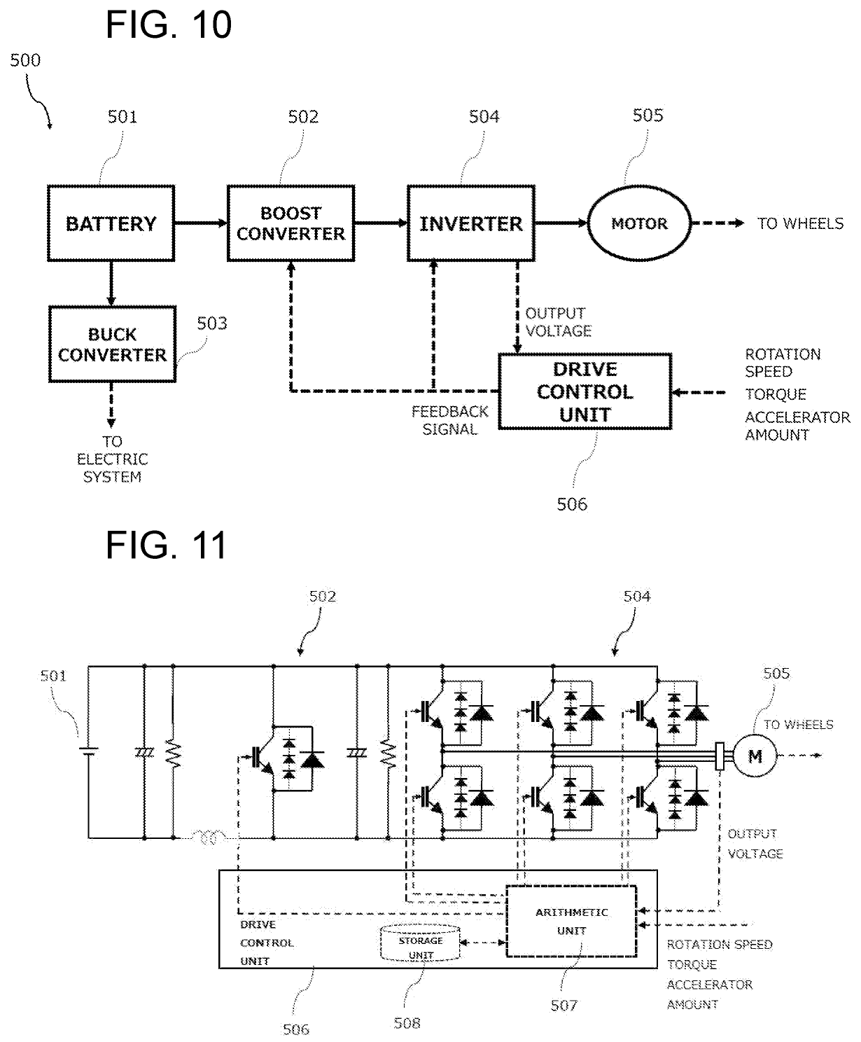

To cause the semiconductor device of the disclosure described above to fulfill the foregoing function, this semiconductor device may be applied to a power converter such as an inverter or a converter. More preferably, the semiconductor device may be applied as a diode provided in an inverter or a converter and may be used in combination with a switching element that may be a thyristor, a power transistor, an IGBT (insulated gate bipolar transistor), or the MOSFET for synchronous rectification illustrated in FIG. 9, for example. FIG. 10 is a block configuration diagram showing an example of a control system using the semiconductor device according to the embodiment of the disclosure. FIG. 11 is a circuit diagram of this control system, which is a circuit diagram of a control system to be mounted particularly suitably on an electric vehicle.

As shown in FIG. 10, the control system 500 includes a battery (power supply) 501, a boost converter 502, a buck converter 503, an inverter 504, a motor (driving object) 505, a drive control unit 506, which are mounted on an electric vehicle. The battery 501 consists of, for example, a storage battery such as a nickel hydrogen battery or a lithium-ion battery. The battery 501 can store electric power by charging at the power supply station or regenerating at the time of deceleration, and to output a direct current (DC) voltage required for the operation of the driving system and the electrical system of the electric vehicle. The boost converter 502 is, for example, a voltage converter in which a chopper circuit is mounted, and can step-up DC voltage of, for example, 200 V supplied from the battery 501 to, for example, 650 V by switching operations of the chopper circuit. The step-up voltage can be supplied to a traveling system such as a motor. The buck converter 503 is also a voltage converter in which a chopper circuit is mounted, and can step-down DC voltage of, for example, 200 V supplied from the battery 501 to, for example, about 12 V. The step-down voltage can be supplied to an electric system including a power window, a power steering, or an electric device mounted on a vehicle.

The inverter 504 converts the DC voltage supplied from the boost converter 502 into three-phase alternating current (AC) voltage by switching operations, and outputs to the motor 505. The motor 505 is a three-phase AC motor constituting the traveling system of an electric vehicle, and is driven by an AC voltage of the three-phase output from the inverter 504. The rotational driving force is transmitted to the wheels of the electric vehicle via a transmission mechanism (not shown).

On the other hand, actual values such as rotation speed and torque of the wheels, the amount of depression of the accelerator pedal (accelerator amount) are measured from an electric vehicle in cruising by using various sensors (not shown), The signals thus measured are input to the drive control unit 506. The output voltage value of the inverter 504 is also input to the drive control unit 506 at the same time. The drive control unit 506 has a function of a controller including an arithmetic unit such as a CPU (Central Processing Unit) and a data storage unit such as a memory, and generates a control signal using the inputted measurement signal and outputs the control signal as a feedback signal to the inverters 504, thereby controlling the switching operation by the switching elements. The AC voltage supplied to the motor 505 from the inverter 504 is thus corrected instantaneously, and the driving control of the electric vehicle can be executed accurately. Safety and comfortable operation of the electric vehicle is thereby realized. In addition, it is also possible to control the output voltage to the inverter 504 by providing a feedback signal from the drive control unit 506 to the boost converter 502.

FIG. 11 is a circuit configuration excluding the buck converter 503 in FIG. 10, in other words, a circuit configuration showing a configuration only for driving the motor 505. As shown in the FIG. 11, the semiconductor device of the disclosure is provided for switching control by, for example, being applied to the boost controller 502 and the inverter 504 as a Schottky barrier diode. The boost converter 502 performs chopper control by incorporating the semiconductor device into the chopper circuit of the boost converter 502. Similarly, the inverter 504 performs switching control by incorporating the semiconductor device into the switching circuit including an IGBT of the inverter 504. The current can be stabilized by interposing an inductor (such as a coil) at the output of the battery 501. Also, the voltage can be stabilized by interposing a capacitor (such as an electrolytic capacitor) between each of the battery 501, the boost converter 502, and the inverter 504.

As indicated by a dotted line in FIG. 11, an arithmetic unit 507 including a CPU (Central Processing Unit) and a storage unit 508 including a nonvolatile memory are provided in the drive control unit 506. Signal input to the drive control unit 506 is given to the arithmetic unit 507, and a feedback signal for each semiconductor element is generated by performing the programmed operation as necessary. The storage unit 508 temporarily holds the calculation result by the calculation unit 507, stores physical constants and functions necessary for driving control in the form of a table, and outputs the physical constants, functions, and the like to the arithmetic unit 507 as appropriate. The arithmetic unit 507 and the storage unit 508 can be provided by a known configuration, and the processing capability and the like thereof can be arbitrarily selected.

As shown in FIGS. 10 and 11, a diode and a switching element such as a thyristor, a power transistor, an IGBT, a MOSFET and the like is employed for the switching operation of the boost converter 502, the buck converter 503 and the inverter 504 in the control system 500. The use of gallium oxide (Ga 2 O3) specifically corundum-type gallium oxide (α —Ga 2 O3) as its materials for these semiconductor devices greatly improves switching properties. Further, extremely outstanding switching performance can be expected and miniaturization and cost reduction of the control system 500 can be realized by applying a semiconductor film or a semiconductor device of the disclosure. That is, each of the boost converter 502, the buck converter 503 and the inverter 504 can be expected to have the benefit of the disclosure, and the effect and the advantages can be expected in any one or combination of the boost converter 502, the buck converter 503 and the inverter 504, or in any one of the boost converter 502, the buck converter 503 and the inverter 504 together with the drive control unit 506. The control system 500 described above is not only applicable to the control system of an electric vehicle of the semiconductor device of the disclosure, but can be applied to a control system for any applications such as to step-up and step-down the power from a DC power source, or convert the power from a DC to an AC. It is also possible to use a power source such as a solar cell as a battery.

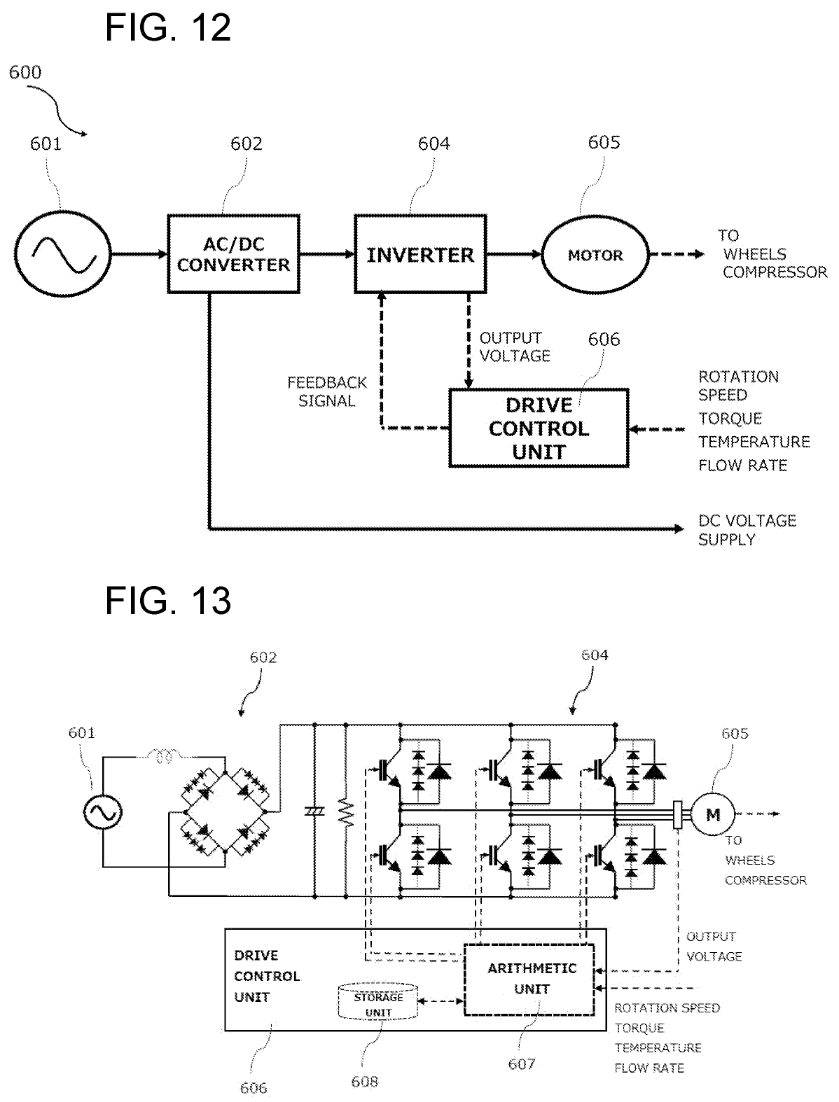

FIG. 12 is a block diagram illustrating another exemplary control system applying a semiconductor device according to an embodiment of the disclosure, and FIG. 13 is a circuit diagram of the control system suitable for applying to infrastructure equipment and home appliances or the like operable by the power from the AC power source.

As shown in FIG. 12, the control system 600 is provided for inputting power supplied from an external, such as a three-phase AC power source (power supply) 601, and includes an AC/DC converter 602, an inverter 604, a motor (driving object) 605 and a drive control unit 606 that can be applied to various devices described later. The three-phase AC power supply 601 is, for example, a power plant (such as a thermal, hydraulic, geothermal, or nuclear plant) of an electric power company, whose output is supplied as an AC voltage while being downgraded through substations. Further, the three-phase AC power supply 601 is installed in a building or a neighboring facility in the form of a private power generator or the like for supplying the generated power via a power cable. The AC/DC converter 602 is a voltage converter for converting AC voltage to DC voltage. The AC/DC converter 602 converts AC voltage of 100 V or 200 V supplied from the three-phase AC power supply 601 to a predetermined DC voltage. Specifically, AC voltage is converted by a transformer to a desired, commonly used voltage such as 3. 3 V, 5 V, or 12 V. When the driving object is a motor, conversion to 12 V is performed. It is possible to adopt a single-phase AC power supply in place of the three-phase AC power supply. In this case, same system configuration can be realized if an AC/DC converter of the single-phase input is employed.

The inverter 604 converts the DC voltage supplied from the AC/DC converter 602 into three-phase AC voltage by switching operations and outputs to the motor 605. Configuration of the motor 605 is variable depending on the control object. It can be a wheel if the control object is a train, can be a pump and various power source if the control objects a factory equipment, can be a three-phase AC motor for driving a compressor or the like if the control object is a home appliance. The motor 605 is driven to rotate by the three-phase AC voltage output from the inverter 604, and transmits the rotational driving force to the driving object (not shown).

There are many kinds of driving objects such as personal computer, LED lighting equipment, video equipment, audio equipment and the like capable of directly supplying a DC voltage output from the AC/DC inverter 602. In that case the inverter 604 becomes unnecessary in the control system 600, and a DC voltage from the AC/DC inverter 602 is supplied to the driving object directly as shown in FIG. 12. Here, DC voltage of 3. 3 V is supplied to personal computers and DC voltage of 5 V is supplied to the LED lighting device for example.

On the other hand, rotation speed and torque of the driving object, measured values such as the temperature and flow rate of the peripheral environment of the driving object, for example, is measured using various sensors (not shown), these measured signals are input to the drive control unit 606. At the same time, the output voltage value of the inverter 604 is also input to the drive control unit 606.

Based on these measured signals, the drive control unit 606 provides a feedback signal to the inverter 604 thereby controls switching operations by the switching element of the inverter 604. The AC voltage supplied to the motor 605 from the inverter 604 is thus corrected instantaneously, and the operation control of the driving object can be executed accurately. Stable operation of the driving object is thereby realized. In addition, when the driving object can be driven by a DC voltage, as described above, feedback control of the AC/DC controller 602 is possible in place of feedback control of the inverter.

FIG. 13 shows the circuit configuration of FIG. 12. As shown in FIG. 13, the semiconductor device of the disclosure is provided for switching control by, for example, being applied to the AC/DC converter 602 and the inverter 604 as a Schottky barrier diode. The AC/DC converter 602 has, for example, a circuit configuration in which Schottky barrier diodes are arranged in a bridge-shaped, to perform a direct-current conversion by converting and rectifying the negative component of the input voltage to a positive voltage. Schottky barrier diodes can also be applied to a switching circuit in IGBT of the inverter 604 to perform switching control. The voltage can be stabilized by interposing a capacitor (such as an electrolytic capacitor) between the AC/DC converter 602 and the inverter 604.

As indicated by a dotted line in FIG. 13, an arithmetic unit 607 including a CPU and a storage unit 608 including a nonvolatile memory are provided in the drive control unit 606. Signal input to the drive control unit 606 is given to the arithmetic unit 607, and a feedback signal for each semiconductor element is generated by performing the programmed operation as necessary. The storage unit 608 temporarily holds the calculation result by the arithmetic unit 607, stores physical constants and functions necessary for driving control in the form of a table, and outputs the physical constants, functions, and the like to the arithmetic unit 607 as appropriate. The arithmetic unit 607 and the storage unit 608 can be provided by a known configuration, and the processing capability and the like thereof can be arbitrarily selected.

In such a control system 600, similarly to the control system 500 shown in FIGS. 10 and 11, a diode or a switching element such as a thyristor, a power transistor, an IGBT, a MOSFET or the like is also applied for the purpose of the rectification operation and switching operation of the AC/DC converter 602 and the inverter 604.

Switching performance can be improved by the use of gallium oxide (Ga₂O₃), particularly corundum-type gallium oxide (α—Ga₂O₃), as materials for these semiconductor elements. Further, extremely outstanding switching performance can be expected and miniaturization and cost reduction of the control system 600 can be realized by applying a semiconductor film or a semiconductor device of the disclosure. That is, each of the AC/DC converter 602 and the inverter 604 can be expected to have the benefit of the disclosure, and the effects and the advantages of the disclosure can be expected in any one or combination of the AC/DC converter 602 and the inverter 604, or in any of the AC/DC converter 602 and the inverter 604 together with the drive control unit 606.

Although the motor 605 has been exemplified in FIGS. 12 and 13, the driving object is not necessarily limited to those that operate mechanically. Many devices that require an AC voltage can be a driving object. It is possible to apply the control system 600 as long as electric power is obtained from AC power source to drive the driving object. The control system 600 can be applied to the driving control of any electric equipment such as infrastructure equipment (electric power facilities such as buildings and factories, telecommunication facilities, traffic control facilities, water and sewage treatment facilities, system equipment, labor-saving equipment, trains and the like) and home appliances (refrigerators, washing machines, personal computers, LED lighting equipment, video equipment, audio equipment and the like).

While each of the embodiments of the disclosure has been described above, the disclosure shall not be limited to these embodiments but the disclosure certainly becomes implementable by being modified in various ways within a range not deviating from the purport of the disclosure.

For example, in the above-described first to fourth embodiments, only one PN junction diode is mounted directly on the die pad common to the Schottky barrier diode. In another case, two or three PN junction diodes may be mounted two-dimensionally on the die pad common to the Schottky barrier diode. This makes it possible to improve durability against an overcurrent further and to facilitate design of the die pad. If the Schottky barrier diode and a plurality of PN junction diodes are all to be mounted on the common die pad, one die pad is sufficient. In this case, providing one vertical PN junction diode and configuring the other PN junction diode as a horizontal PN junction diode facilitates mutual electrical connection between the diodes including the Schottky barrier diode, allowing the diodes to the mounted on the same pad extremely easily. Moreover, as shown in the fifth embodiment, stacking some of a plurality of PN junction diodes on each other makes it possible to reduce a total area of the die pad or reduce a mounting area of the semiconductor further.

Preferably, the die pad on which the PN junction diode and the Schottky barrier diode are mounted commonly is composed of a single member. As long as sufficient thermal connection is provided, however, the die pad is not always required to be a single member. More specifically, even if the PN junction diode and the Schottky barrier diode are mounted on respective die pads, thermally connecting these two die pads to each other through a connector having a high thermal conductivity or using a single material (copper, for example) for forming all the two die pads and the connector is expected to achieve effect comparable to that achieved in a case where these members are formed integrally.

The number of the series-connected PN junction diodes is not limited to three. By giving consideration to a relationship between a forward voltage of the Schottky barrier diode and a forward voltage of the PN junction diode to be employed (FIG. 8), a surge breakdown voltage, a reverse breakdown voltage, etc., an arbitrary number becomes settable. In this case, while it is also required to set a total of breakdown voltages of a plurality of PN junction diodes greater than a breakdown voltage of the Schottky barrier diode, a smaller difference in breakdown voltage therebetween is preferred. Preferably, the total of the breakdown voltages and the breakdown voltage of the Schottky barrier diode are set substantially equal to each other.

The size or shape of the die pad on the semiconductor device is not limited to that illustrated in the drawings. The Schottky barrier diode or the PN junction diode is mountable on any die pad within a range in which durability against overcurrent is maintainable.

Not only electrical connection through solder or wire bonding is employed for connection between a plurality of PN junction diodes but these PN junction diodes are connectable with a ribbon wire or a copper clip, for example.

In FIGS. 11 or 13, for example, design is preferably made in such a manner that both a total of breakdown voltages of a plurality of PN junction diodes and a breakdown voltage of a Schottky barrier diode become less than a breakdown voltage of a switching element connected in parallel to the PN junction diodes and the Schottky barrier diode.

It is certainly possible to combine two or more embodiments according to the disclosure or apply some constituting elements to other embodiments. Such configurations also belong to the embodiments of the disclosure.

The embodiments of the present invention are exemplified in all respects, and the scope of the present invention includes all modifications within the meaning and scope equivalent to the scope of claims.

Reference Signs List

| 2a, 2b, 2c, 2d, 2e, 11, 12, 13 | PN junction diode |
|---|---|
| 3 | Schottky barrier diode |
| 4a, 4b, 4c | Die pad |
| 4 a 1 | First area (first pad area) |
| 4 a 2 | Second area (second pad area) |
| 5, 6 | Terminal |
| 7a, 7b, 7c, 7d, 7e, 8 | Lead |
| 10 | Package |
| 14 | MOSFET (metal-oxide-semiconductor field effect transistor) |
| 100, 110, 120, 130, 140, 150 | Semiconductor device |
| 500 | control system |
| 501 | battery (power supply) |
| 502 | boost converter |
| 503 | buck converter |
| 504 | inverter |
| 505 | motor (driving object) |
| 506 | drive control unit |
| 507 | arithmetic unit |
| 508 | storage unit |
| 600 | control system |
| 601 | three-phase AC power supply |
| 602 | AC/DC converter |
| 604 | inverter |
| 605 | motor (driving object) |
| 606 | drive control unit |
| 607 | arithmetic unit |
| 608 | storage unit |

What is claimed is:

1. A semiconductor device comprising:
a plurality of PN junction diodes each having a negative temperature characteristic and connected to each other in series;
a Schottky barrier diode having a positive temperature characteristic and connected to the PN junction diodes in parallel; and
a die pad on which at least one of the PN junction diodes and the Schottky barrier diode are mounted commonly.

2. The semiconductor device according to claim 1, wherein
a total of respective forward voltages of the PN junction diodes is greater than a forward voltage of the Schottky barrier diode.

3. The semiconductor device according to claim 1, wherein
at least one of the PN junction diodes is a vertical diode.

4. The semiconductor device according to claim 1, wherein
at least one of the PN junction diodes is stacked on a different one of the PN junction diodes.

5. The semiconductor device according to claim 1, wherein
all the PN junction diodes are mounted on the same die pad.

6. The semiconductor device according to claim 1, wherein
each of the PN junction diodes contains silicon.

7. The semiconductor device according to claim 1, wherein
the PN junction diodes include a PiN diode.

8. The semiconductor device according to claims 1, wherein
the Schottky barrier diode contains gallium oxide or mixed crystal of gallium oxide.

9. A semiconductor device comprising:
a plurality of PN junction diodes each having a negative temperature characteristic and connected to each other in series;
a Schottky barrier diode having a positive temperature characteristic and connected to the PN junction diodes in parallel;
a plurality of first die pad areas on which the PN junction diodes are mounted; and
a second die pad area on which the Schottky barrier diode is mounted,
at least one of the first die pad areas and the second die pad area being thermally connected to each other.

10. The semiconductor device according to claim 9, wherein
at least one of the first die pad areas and the second die pad area are formed integrally with each other.

11. The semiconductor device according to claim 9, wherein
a total of respective forward voltages of the PN junction diodes is greater than a forward voltage of the Schottky barrier diode.

12. The semiconductor device according to claim 9, wherein
at least one of the PN junction diodes is a vertical diode.

13. The semiconductor device according to claim 9, wherein
at least one of the PN junction diodes is stacked on a different one of the PN junction diodes.

14. The semiconductor device according to claim 9, wherein
all the PN junction diodes are mounted on the same die pad area.

15. The semiconductor device according to claim 9, wherein
each of the PN junction diodes contains silicon.

16. The semiconductor device according to claim 9, wherein
the PN junction diodes include a PiN diode.

17. The semiconductor device according to claim 9, wherein
the Schottky barrier diode contains gallium oxide or mixed crystal of gallium oxide.

18. A semiconductor device comprising:
a PN junction diode having a negative temperature characteristic;
a MOSFET (metal-oxide-semiconductor field effect transistor) having a positive temperature characteristic and connected to the PN junction diode in parallel; and
a die pad on which the PN junction diode and the MOSFET are mounted commonly.

19. A semiconductor device comprising:
a PN junction diode having a negative temperature characteristic;
a MOSFET (metal-oxide-semiconductor field effect transistor) having a positive temperature characteristic and connected to the PN junction diode in parallel;
a first die pad area on which the PN junction diode are mounted; and
a second die pad area on which the MOSFET is mounted,
the first die pad area and the second die pad area being thermally connected to each other.

20. A power converter using the semiconductor device according to claim 1.

21. A control system using the semiconductor device according to claim 1.
